(19) United States
(12) Patent Application Publication
(10) Pub. No.: US 2010/0248413 A1
(43) Pub. Date: Sep. 30, 2010

(54) Monolithic Integration of Photovoltaic Cells

(76) Inventors: David Strand, Bloomfield Twp., MI (US); Stanford R. Ovshinsky, Bloomfield Hills, MI (US)

Correspondence Address: Kevin L. Bray;Ovshinsky Innovation, LLC, 1050 E. Square Lake Road, Bloomfield Hills, MI, 48304, US

(21) Appl. No.: 12/414,689

(22) Filed: Mar. 31, 2009

(51) Int. Cl. H01L 31/02; H01L 21/98

(52) U.S. Cl. 438/67; 257/E31.11; 257/E21.705

(57) ABSTRACT

A method of forming a photovoltaic device on a substrate, especially an opaque substrate. The method includes forming a photovoltaic material on a substrate and removing the substrate. The method may include patterning the photovoltaic material to form a plurality of photovoltaic devices and configuring the devices in series to achieve monolithic integration. The method may include forming additional layers on the substrate, such as one or more of a protective material, a transparent conductor, a back conductor, an adhesive layer, and a laminate support layer. When the substrate is opaque, the method provides the option of ordering the layers so that a transparent conductor is formed before the back reflector of a photovoltaic stack. This ordering of layers facilitates monolithic integration and the ability to remove the substrate allows the earlier-formed transparent conductor to serve as the point of incidence for receiving the light that excites the photovoltaic material. The method enables high speed manufacturing of monolithically integrated photovoltaic devices on opaque substrates.

### FIELD OF INVENTION

This invention relates to the high speed manufacturing of photovoltaic materials. More particularly, this invention relates to formation and integration of solar cells from photovoltaic materials formed on a flexible substrate in a continuous manufacturing process.

### BACKGROUND OF THE INVENTION

Concern over the depletion and environmental impact of fossil fuels has stimulated strong interest in the development of alternative energy sources. Significant investments in areas such as batteries, fuel cells, hydrogen production and storage, biomass, wind power, algae, and solar energy have been made as society seeks to develop new ways of creating and storing energy in an economically competitive and environmentally benign fashion. The ultimate objective is to minimize society's reliance on fossil fuels and to do so in an economically competitive way that minimizes greenhouse gas production.

A number of experts have concluded that to avoid the serious consequences of global warming, it is necessary to maintain CO₂ at levels of 550 ppm or less. To meet this target, based on current projections of world energy usage, the world will need 17 TW of carbon-free energy by the year 2050 and 33 TW by the year 2100. The estimated contribution of various carbon-free sources toward the year 2050 goal are summarized below:

| | Projected Energy |
|---|---|
| Source | Supply (TW) |
| Wind | 2-4 |
| Tidal | 2 |
| Hydro | 1.6 |
| Biofuels | 5-7 |
| Geothermal | 2-4 |
| Solar | 600 |

Based on the expected supply of energy from the available carbon-free sources, it is apparent that solar energy is the only viable solution for reducing greenhouse emissions and alleviating the effects of global climate change.

Unless solar energy becomes cost competitive with fossil fuels, however, society will lack the motivation to eliminate its dependence on fossil fuels and will refrain from adopting solar energy on the scale necessary to meaningfully address global warming. As a result, current efforts in manufacturing are directed at reducing the unit cost (cost per kilowatt-hour) of energy produced by photovoltaic materials and products.

The general strategies for decreasing the unit cost of energy from photovoltaic products are reducing process costs and improving photovoltaic efficiency. Efforts at reducing process costs are directed to identifying low cost photovoltaic materials and increasing process speeds. Crystalline silicon is currently the dominant photovoltaic material because of its wide availability in bulk form. Crystalline silicon, however, possesses weak absorption of solar energy because it is an indirect gap material. As a result, photovoltaic modules made from crystalline silicon are thick, rigid and not amenable to lightweight, thin film products.

Materials with stronger absorption of the solar spectrum are under active development for photovoltaic products. Representative materials include CdS, CdSe, CdTe, ZnTe, CIGS (Cu—In—Ga—Se and related alloys), organic materials (including organic dyes), and TiO₂. These materials offer the prospect of reduced material costs because their high solar absorption efficiency permits photovoltaic operation with thin films, thus reducing the volume of material needed to manufacture devices.

Amorphous silicon (and hydrogenated and/or fluorinated forms thereof) is another attractive photovoltaic material for lightweight, efficient, and flexible thin-film photovoltaic products. Stanford R. Ovshinsky is the seminal figure in modern thin film semiconductor technology. Early on, he recognized the advantages of amorphous silicon (as well as amorphous germanium, amorphous alloys of silicon and germanium, including doped, hydrogenated and fluorinated versions thereof) as a solar energy material. He was the first to recognize the advantages of nanocrystalline silicon as a photovoltaic material. He was also the first to understand the physics and practical benefits of intermediate range order materials and multilayer photovoltaic devices. For representative contributions of S. R. Ovshinsky in the area of photovoltaic materials see U.S. Pat. No. 4,217,374 (describing suitability of amorphous silicon and related materials as the active material in several semiconducting devices); U.S. Pat. No. 4,226,898 (demonstration of solar cells having multiple layers, including n- and p-doped); and U.S. Pat. No. 5,103,284 (deposition of nanocrystalline silicon and demonstration of advantages thereof); as well as his article entitled “The material basis of efficiency and stability in amorphous photovoltaics” (Solar Energy Materials and Solar Cells, vol. 32, p. 443-449 (1994)).

Approaches for increasing process speed include: (1) increasing the intrinsic deposition rates of the different materials and layers used to manufacture photovoltaic devices and (2) adopting a continuous, instead of a batch, manufacturing process. S. R. Ovshinsky has pioneered the automated and continuous manufacturing techniques needed to produce thin film, flexible large-area solar panels based on amorphous, nanocrystalline, microcrystalline, polycrystalline or composite materials. Although his work has emphasized the silicon and germanium systems, the manufacturing techniques that he has developed are universal to all material systems. Representative contributions of S. R. Ovshinsky to the field of photovoltaic manufacturing are included in U.S. Pat. No. 4,400,409 (describing a continuous manufacturing process for making thin film photovoltaic films and devices); U.S. Pat. No. 4,410,588 (describing an apparatus for the continuous manufacturing of thin film photovoltaic solar cells); U.S. Pat. No. 4,438,723 (describing an apparatus having multiple deposition chambers for the continuous manufacturing of multilayer photovoltaic devices); and U.S. Pat. No. 5,324,553 (microwave deposition of thin film photovoltaic materials).

S. R. Ovshinsky has also recently presented a breakthrough in the deposition rate of materials in the amorphous silicon system and has described a process and apparatus of achieving deposition rates on the scale of hundreds of Angstroms per second. The method involves a pre-selection of preferred deposition species in a plasma deposition process and delivery of the preferred deposition species in relatively pure form to a deposition process. By removing deleterious species normally present in the plasma activation of silane, germane, and other common deposition precursor, S. R. Ovshinsky has demonstrated a remarkable increase in deposition rate without sacrificing photovoltaic performance by insuring that nearly defect-free material forms in the as-deposited state. (See U.S. patent application Ser. Nos. 12/199,656; 12/199,712; 12/209,699; and 12/316,417.)

A second general approach for decreasing the unit cost of energy from photovoltaic products is to improve photovoltaic efficiency. As noted above, photovoltaic efficiency can be improved through the selection of the active photovoltaic material. Efficiency can also be improved through the design of the photovoltaic product. Efficiency depends not only on the characteristics of the photovoltaic material (absorption efficiency, quantum efficiency, carrier lifetime, and carrier mobility), but also on the surrounding device structure. Photogenerated charge carriers need to be efficiently extracted from the photovoltaic material and delivered to the outer contacts of the photovoltaic product to provide power to an external load. To maximize performance, it is necessary to recover the highest possible fraction of photogenerated carriers and to minimize losses in energy associated with transporting photogenerated carriers to the outer contacts. Accordingly, it is desirable to maximize both the photovoltaic current and voltage.

Higher operational voltages for photovoltaic products tend to reduce losses associated with carrier transport and during delivery of power to external loads. Due to intrinsic recombination processes, however, the maximum output voltage available from a particular photovoltaic material is below the voltage preferred for minimizing power losses. To overcome this problem, it is common to integrate several photovoltaic devices in a series configuration to boost the output voltage of the photovoltaic product. The simplest approach to series integration entails producing multiple standalone photovoltaic modules, where each module includes an active area of photovoltaic material interposed between two outer contacts, and joining the outer contacts of the individual modules in series. This approach, however, suffers from the drawback that it is difficult to automate and has proven costly to incorporate into a manufacturing process. This approach also becomes more difficult to implement as the active area of the photovoltaic material decreases due to the need to join ever smaller contacts.

An alternative approach to series integration is a process known as monolithic integration. In monolithic integration, series integration is achieved by first patterning the photovoltaic material within a given module to form a series of small area photovoltaic devices on the same wafer or substrate and then connecting the individual photovoltaic devices via a metallization or junction scheme to selectively connect devices in a series configuration. Monolithic integration permits series integration of a large number of individual devices to produce a significant output voltage for the module as a whole.

In a typical monolithic integration scheme, a photovoltaic device is formed on a glass substrate. A common photovoltaic device is a multilayer structure that includes a transparent conductive oxide formed on the glass substrate, a photovoltaic material formed over the transparent conductive oxide, and a reflective (normally metallic) back conductor formed over the photovoltaic material. Monolithic integration is performed by patterning or segmenting the layers to define a series of electrically isolated devices. The patterning includes the selective formation of features (e.g. trenches or vias) to spatially separate individual devices and define a pattern of contacts, and filling those features with a conductive material to form contacts that achieve series integration of the individual devices. Each of several layers may be patterned and the patterns formed in the different layers can be offset or otherwise arranged to facilitate the formation of series connections between adjacent devices.

The patterning of the individual layers may be accomplished by laser scribing, where a laser is used to selectively remove material in one or more of the layers of the device structure during fabrication to form an isolation feature that segments individual devices. Laser scribing is a particularly advantageous patterning technique because it eliminates the need for photolithographic masking and etching techniques and reduces the time and cost of processing accordingly. Since some material compositions are not amenable to laser scribing, monolithic integration may include a combination of laser scribing and masking and etching or other techniques.

For reasons of processing convenience, work to date in the area of monolithic integration has emphasized photovoltaic devices formed on transparent substrates. Transparent substrates offer two processing advantages. First, substrate transparency permits patterning of layers with optical sources through the substrate. By controlling the depth of focus and wavelength of laser irradiation, for example, selected device layers can be patterned without disturbing other layers. This approach is advantageous because it allows for post-fabrication device integration.

Substrate transparency is also advantageous in processing schemes that incorporate patterning into the fabrication sequence. It is common, for example, during fabrication to deposit a particular layer and pattern it before depositing succeeding layers of a photovoltaic stack. When patterning immediately follows deposition of a layer, patterning need not occur through the substrate and can instead occur at the exposed surface of the layer. In such processes, substrate transparency does not necessarily provide an advantage in terms of patterning, but does remain beneficial from the standpoint of the ordering of layers during fabrication. In particular, in photovoltaic device applications, a transparent substrate can receive the incident light and transmit it to the underlying layers of the device structure. As a result, the transparent conductive contact can be formed directly on the transparent substrate and patterned, the photovoltaic material can then be deposited and patterned, and the reflective back conductor layer can be formed still later in the fabrication process. This sequencing of layers is more conducive to monolithic integration than a reverse sequence in which the back reflector is deposited early in the fabrication process and the transparent conductive layer is deposited late in the fabrication process.

Transparent substrates are disadvantageous from the point of view of high speed manufacturing, however, because they tend to be brittle and susceptible to fracture or scratching during substrate transport and handling. High speed continuous web manufacturing is best performed with durable substrates. Materials, like steel, that are mechanically robust, preferably at thin dimensions, are commonly used in high speed manufacturing processes. From the perspective of monolithic integration, however, steel is disadvantageous because it is an opaque material and thus cannot serve as a window either for laser patterning of deposited layers or as an entry point for receiving the incident light used to operate the photovoltaic device.

Because of the opacity of metal substrates, high speed manufacturing of photovoltaic devices on metal substrates employ a design in which the transparent conductive layer is deposited at or near the top of the device stack during fabrication so that it can serve as a window for receiving incident light. The back conductor layer is deposited near the substrate. The required ordering of layers on metal substrates complicates the steps needed to realize monolithic integration and further creates a need to electrically isolate the back reflector layer from the metal substrate to avoid shorting.

There is a need in the art for a method of manufacturing monolithically integrated photovoltaic devices that combines the beneficial ordering of layers available from transparent substrates with the desirable high speed manufacturing attributes of opaque substrates.

### SUMMARY OF THE INVENTION

This invention provides a method for achieving monolithic integration of photovoltaic materials on transparent or opaque substrates.

In one embodiment, the method includes forming a photovoltaic material over an opaque substrate, forming a laminate over the photovoltaic material, and removing the opaque substrate. In another embodiment, the method further includes patterning the photovoltaic material after removing the opaque substrate.

In one embodiment, the method includes forming a photovoltaic material over an opaque substrate, patterning the photovoltaic material, forming a laminate over the patterned photovoltaic material, and removing the opaque substrate.

In another embodiment, the method includes forming a transparent conductor over an opaque substrate, forming a photovoltaic material over the transparent conductor, forming a laminate over the photovoltaic material, and removing the opaque substrate. In another embodiment, the method further includes patterning the photovoltaic material or the transparent conductor after removing the opaque substrate.

In another embodiment, the method includes forming a transparent conductor over an opaque substrate, patterning the transparent conductor, forming a photovoltaic material over the patterned transparent conductor, patterning the photovoltaic material, forming a laminate over the patterned photovoltaic material, and removing the opaque substrate.

In another embodiment, the method includes forming a transparent conductor over an opaque substrate, forming a photovoltaic material over the transparent conductor, forming a back conductor over the photovoltaic material, forming a laminate over the photovoltaic material, and removing the opaque substrate. In another embodiment, the method further includes patterning the transparent conductor, photovoltaic material, or back conductor after removing the opaque substrate.

In another embodiment, the method includes forming a transparent conductor over an opaque substrate, patterning the transparent conductor, forming a photovoltaic material over the patterned transparent conductor, patterning the photovoltaic material, forming a back conductor over the patterned photovoltaic material, patterning the back conductor, forming a laminate over the patterned back conductor, and removing the opaque substrate.

In one embodiment, the opaque substrate is a metal, such as steel or aluminum. In another embodiment, the opaque substrate is a plastic or polymer, such as Kapton, a polyimide, polyethylene, or mylar.

In one embodiment, patterning is accomplished by laser scribing. In another embodiment, patterning is accomplished by masking and etching.

In one embodiment, the opaque substrate is removed by delamination. In another embodiment, the delaminated opaque substrate is recycled and used for further depositions in accordance with the instant invention. In another embodiment, the opaque substrate is removed by a chemical treatment. The chemical treatment may include dissolution of the substrate. In another embodiment, the opaque substrate is removed by a mechanical process such as cutting, grinding, or polishing.

In an alternative embodiment, a sacrificial layer is deposited on the opaque substrate and a photovoltaic structure having one or more layers is formed on the sacrificial layer. Patterning of one or more of the layers of the photovoltaic structure may occur during the fabrication process. After formation of the photovoltaic structure, the opaque substrate may be removed by shearing the opaque substrate to fracture the sacrificial layer or by dissolution or other chemical treatment of the sacrificial layer.

### BRIEF DESCRIPTION OF THE DRAWING

FIG. 1 depicts a process including forming a photovoltaic material on a substrate and removing the substrate.

FIG. 2 depicts a process of forming a patterned photovoltaic material on a substrate and removing the substrate.

FIG. 3 depicts a process including forming a photovoltaic material and a laminate on a substrate and removing the substrate.

FIG. 4 depicts a process including forming a first conductive layer, a photovoltaic material, and a second conductive layer on a substrate and removing the substrate.

FIG. 5 depicts a process including forming and patterning a first conductive layer, forming and patterning a photovoltaic material, and forming a second conductive layer on a substrate and removing the substrate.

FIG. 6 depicts an embodiment of a multilayer structure including a plurality of photovoltaic devices connected in series.

FIG. 7 depicts an embodiment of a multilayer structure including a plurality of photovoltaic devices connected in series.

FIG. 8 depicts a process for separating a substrate from a photovoltaic stack by removing a sacrificial layer interposed between the substrate and photovoltaic stack.

### DETAILED DESCRIPTION OF THE ILLUSTRATED EMBODIMENTS

Although this invention will be described in terms of certain preferred embodiments, other embodiments that are apparent to those of ordinary skill in the art, including embodiments that do not provide all of the benefits and features set forth herein and including embodiments that provide positive benefits for high-volume manufacturing, are also within the scope of this invention. Accordingly, the scope of the invention is defined only by reference to the appended claims.

As used herein, “on” signifies direct contact of a particular layer with another layer and “over” signifies that a particular layer is mechanically supported by another layer. If a particular layer, for example, is said to be formed on a substrate, the layer directly contacts the substrate. If a particular layer is said to be formed over a substrate, the layer is mechanically supported by the substrate and may or may not make direct contact with the substrate. If a particular layer is said to be formed on another layer, the particular layer directly contacts the other layer. If a particular layer is said to be formed over another layer, the particular layer is supported by the other layer and may or may not contact the other layer.

This invention provides a method of producing photovoltaic materials on substrates. The method generally includes providing a substrate, forming a photovoltaic material thereon, and removing the substrate. The method may further include patterning the photovoltaic material to form a plurality of electrically isolated photovoltaic regions that may further be connected in series through antecedent or subsequent deposition of a conducting or semiconducting material to achieve monolithic integration.

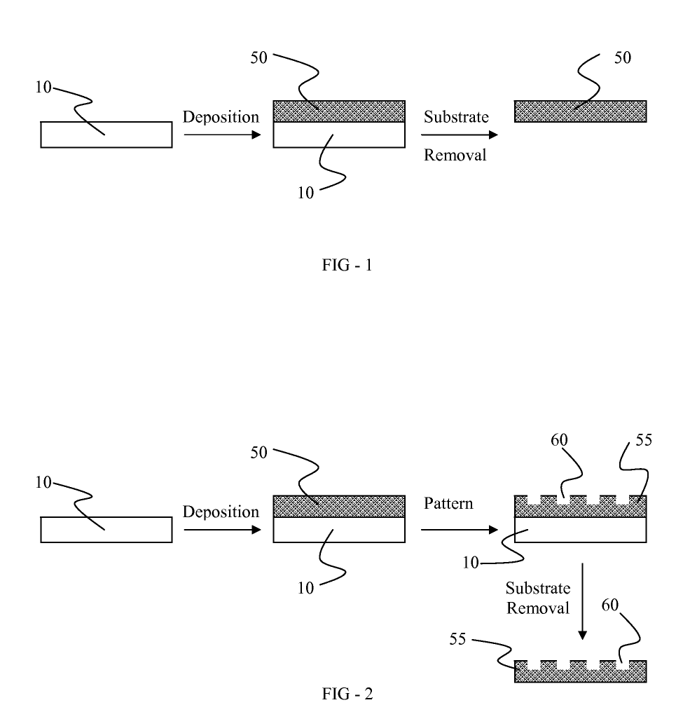

A schematic depiction of a process in accordance with the instant invention is depicted in FIG. 1. The process begins by providing substrate 10 to a deposition process. Photovoltaic material 50 is next formed on substrate 10. Subsequently, substrate 10 is removed to leave photovoltaic material 50 in a free standing form. Note that when photovoltaic material 50 is separated from substrate 10, its surface of contact with substrate 10 becomes exposed and can receive incident light for photoexcitation. Once separated from substrate 10, photovoltaic material 50 may optionally be patterned.

FIG. 2 depicts an alternative embodiment in which photovoltaic material 50 is patterned before substrate 10 is removed. Patterned photovoltaic material 55 includes one or more patterned features 60. After patterning, substrate 10 is removed to provide freestanding patterned photovoltaic material 55. Note that if substrate 10 is opaque, the incident light needed to excite patterned photovoltaic material 55 necessarily is incident on the exposed surface that includes patterned features 60 before removal of substrate 10. After separation of substrate 10, however, the light incident side of patterned photovoltaic material 55 may be opposite to patterned features 60.

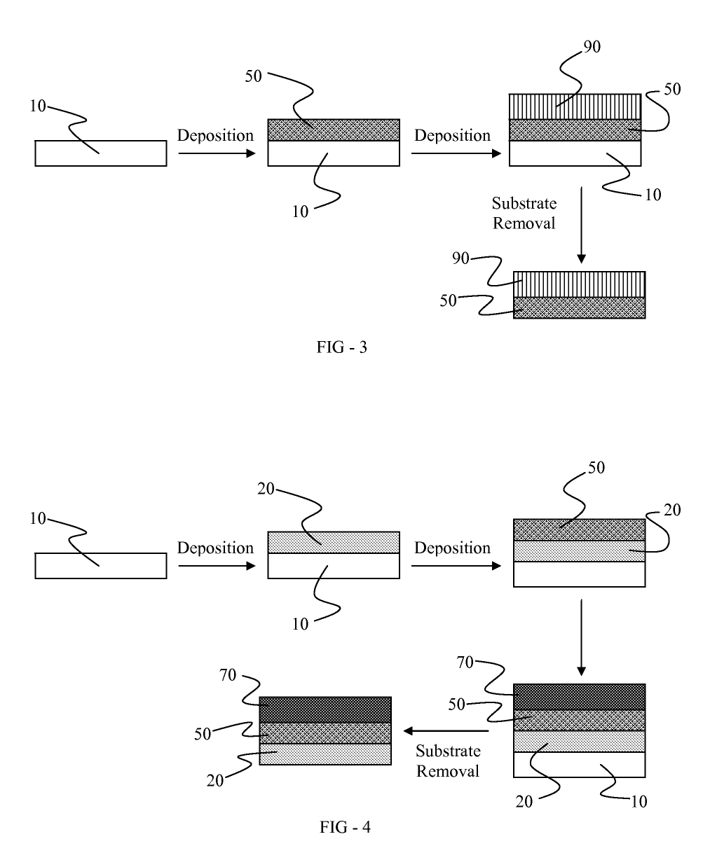

FIG. 3 depicts an alternative embodiment in which laminate 90 is formed on or over photovoltaic material 50. After formation of laminate 90, substrate 10 is removed to provide a composite product that includes photovoltaic material 50 and laminate 90. Inclusion of laminate 90 is beneficial because it provides backing or support for photovoltaic material 50. If photovoltaic material 50 is a fragile or brittle material, it may fracture during the process of removing substrate 10 in the embodiment of FIG. 1 or may not have sufficient mechanical integrity to function as a standalone layer. Laminate 90 provides mechanical support. Laminate 90 may also be formed on or over patterned photovoltaic material 55 shown in FIG. 2.

FIG. 4 depicts an alternative embodiment of a multilayer structure that includes a photovoltaic material interposed between two conductive materials. A first conductive material 20 is formed in a first step on or over substrate 10. Photovoltaic material 50 is next formed on or over first conductive material 20. Second conductive material 70 is then formed on or over photovoltaic material 50 and substrate 10 is subsequently removed. In one embodiment, first conductive material 20 is a transparent conductive material and second conductive material 70 is a reflective layer. When second conductive material 70 is a reflective layer, it may serve as a back reflector of light incident to first conductive material 20 that passes through photovoltaic material 50. As is known in the art, back reflectors improve the efficiency of photovoltaic devices by increasing the fraction of incident light that is converted to photovoltaic energy.

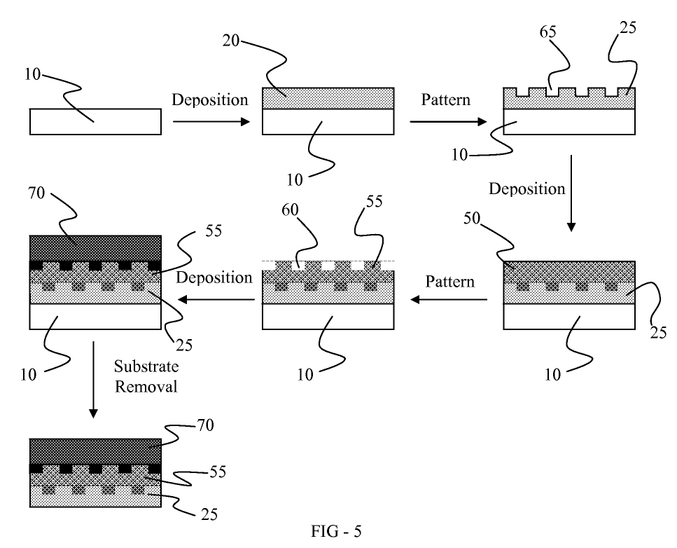

FIG. 5 depicts an alternative embodiment that includes intermediate patterning steps during fabrication. In a first step, a substrate 10 is coated with first conductive material 20. First conductive material 20 is next processed to form patterned conductive material 25 that includes patterned features 65. Photovoltaic material 50 is then formed over patterned conductive material 25 and processed to form patterned photovoltaic material 55 having patterned features 60. Second conductive material 70 is subsequently formed over patterned photovoltaic material 55 and substrate 10 is lastly removed.

In the embodiment depicted in FIG. 5, patterned features 60 are staggered relative to patterned features 65. In other embodiment, patterned features 60 may be aligned with or may overlap patterned features 65. In an alternative embodiment, some of patterned features 60 may be aligned with some of patterned features 65 and others of patterned features 60 may be staggered or overlap others of patterned features 65. In further embodiments, second conductive material 70 may also be patterned. In a further embodiment, a laminate layer may be formed on or over second conductive material 70.

The instant invention generally extends to the formation of multilayer structures that include at least one photovoltaic material. Additional layers in the multilayer structure may include one or more conductive layers, one or more transparent layers, one or more reflective layers, one or more protective layers, one or more adhesive layers and/or one or more laminate layers. A durable transparent layer may be formed, for example, on the substrate so that when the substrate is removed, a protective layer forms an outer surface of the multilayer structure. In one embodiment, a transparent protective layer is formed between the removable substrate and a conductive layer. A laminate layer may also be formed on an adhesive layer that is formed on or over underlying layers of a photovoltaic stack. The adhesive layer may facilitate adhesion of the laminate material to the multilayer stack. In one embodiment, an adhesive layer is formed on or over a conductive layer or a reflective layer (e.g. back reflector) and a laminate material is formed on or over the adhesive layer.

Any, some or all of the layers or material in a multilayer photovoltaic device may be processed to form patterned regions therein. The multilayer structure may include some patterned layers and some unpatterned layers. In some embodiments, all layers may be patterned and in other embodiments, no layers may be patterned. Patterned features within a layer may be arranged periodically or aperiodically. The patterned features within a layer may all have the same shape or may include two or more shapes. The pattern may extend over the full layer or any portion thereof. The patterned features of different layers may be aligned, non-aligned, overlapping, or non-overlapping. The patterned features of different layers may have the same shape or may include two or more shapes.

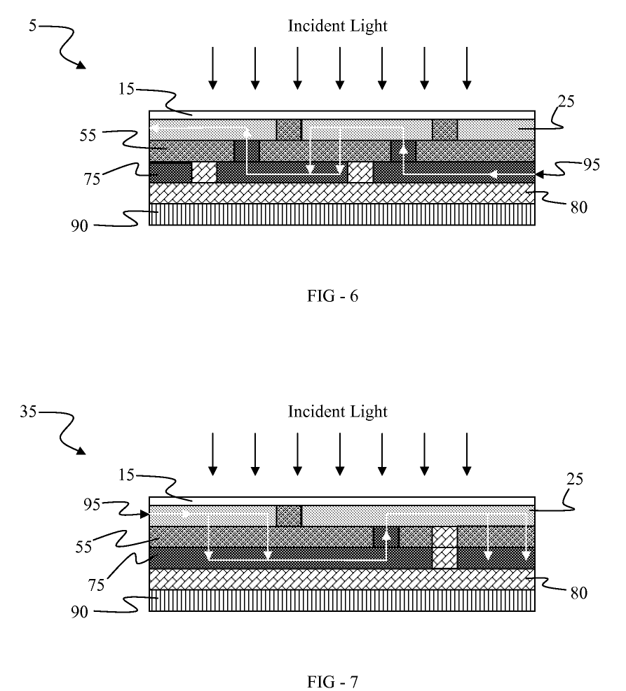

Monolithic integration may be achieved by patterning one or more layers in a multilayer stack to achieve segmentation of the photovoltaic material into a plurality of isolated active regions and then connecting those active regions in series. One portion of an embodiment of a monolithically integrated multilayer photovoltaic structure is shown in FIG. 6. Multilayer structure 5 includes transparent protective layer 15, patterned transparent conductor 25, patterned photovoltaic material 55, patterned back conductor 75, adhesive layer 80 and laminate 90. Patterned photovoltaic material 55 includes segmented regions of the active photovoltaic material that are arranged in a series configuration. Current flow 95 through multilayer structure 5 is shown. The direction of incident light is also shown. Multilayer structure 5 is depicted after removal of the substrate. In a typical embodiment, the substrate would be in closest proximity to transparent protective layer 15 and laminate 90 would be most remote from the substrate before substrate removal. A second example of a monolithically integrated multilayer photovoltaic device 35 is shown in FIG. 7, where the reference numerals correspond to those shown in FIG. 6.

Substrates in accordance with the instant invention include transparent substrates and opaque substrates. The substrate may be an inorganic material (e.g. glass, dielectric, metal, or semiconductor) or an organic material (e.g. polymer, plastic). Representative substrates include silica glass, oxide glass, oxide dielectric, steel, aluminum, silicon, Kapton or other polyimide, polyethylene, Plexiglas or mylar. Preferably the substrate is sufficiently durable to withstand rapid transport in a high speed continuous manufacturing process.

Photovoltaic materials in accordance with the instant invention include amorphous silicon (a-Si), alloys of amorphous silicon (e.g. amorphous silicon-germanium alloys), nanocrystalline silicon, nanocrystalline alloys of silicon, microcrystalline silicon, microcrystalline alloys of silicon, and modified forms thereof (e.g. hydrogenated or fluorinated forms); CdS, CdTe, ZnSe, ZnS, CIGS (Cu—In—Ga—Se), and related materials; TiO₂ or other metal oxides, including doped or activated forms thereof, and organic dyes. The photovoltaic material is preferably a thin film material. The instant invention further extends to multilayer photovoltaic materials, such as tandem devices, triple cell devices, pn devices, np devices, pin devices, nip devices, or other multilayer devices including discrete or graded compositions that may also provide bandgap tuning to better match the absorption of the photovoltaic material with the solar or other electromagnetic spectrum. Multilayer photovoltaic materials may be formed from a combination of two or more of the foregoing photovoltaic materials, including two or more alloys that differ in the relative proportions of the constituent atoms.

The photovoltaic material may be prepared via a solution deposition process (including the sol-gel process), a chemical vapor deposition process (including MOCVD, PECVD (at radiofrequencies or microwave frequencies), or a physical vapor deposition process (e.g. evaporation, sublimation, sputtering).

Patterning of any of the one or more layers of a photovoltaic stack may be accomplished by any of the techniques known in the art. Laser scribing, for example, provides a flexible method for selectively removing portions of a layer to produce a desired pattern of features. A particular pattern may include a plurality of features that differ in size, shape, or depth, where the features are arranged in a linear, periodic, curved, or random configuration.

In an alternative embodiment, patterning is accomplished through a masking process, such as is known in the art of photolithography, where a variety of negative and positive resist chemistries are known and amenable to the instant invention. In a typical process, a resist material is formed on the surface of the layer to be patterned. The resist material may then be patterned by superimposing a mask over the resist, where the mask represents the positive or negative image of the desired pattern. The unmasked portions of the resist are then chemically or photochemically modified to create a solubility contrast between the masked and unmasked portions of the resist. Depending on the particular chemistry, either the masked or unmasked portions of the resist are removed to expose the underlying layer. The exposed portions of the underlying layer may then be processed selectively relative to the unexposed portions of the underlying layer to form a pattern. Patterned features in accordance with the instant invention include trenches, vias, openings, holes, lines, and depressions.

Transparent conductive materials in accordance with the instant invention include transparent conductive oxides, such as ITO (indium tin oxide), ZnO, and related materials. The transparent conductive material may be prepared via a solution deposition process (including the sol-gel process), a chemical vapor deposition process (including MOCVD, PECVD (at radiofrequencies or microwave frequencies), or a physical vapor deposition process (e.g. evaporation, sublimation, sputtering).

Back conductor materials in accordance with the instant invention include metals (e.g. Al, Ag, Cu), conductive oxides (e.g. ZnO, ITO), conductive chalcogenides (e.g. ZnS, ZnTe, ZnSe, CdS) and combinations thereof. The back conductor material may also be a reflective material. As a reflective material, the back conductor reflects light transmitted through the photovoltaic material back into the photovoltaic material to increase the utilization of light and minimize losses. Composite back conductors include combinations of a transparent conductive oxide and a metal (e.g. ZnO+metal). Metallic back conductor materials are typically formed by sputtering or evaporation, but may be formed by other techniques known in the art as well. In one embodiment, the back conductor is textured.

Insulating adhesive layers aid adhesion of the back conductor or back reflector to a laminate or other backing material. The insulating adhesive layer may be a plastic, polymer, or dielectric (e.g. oxide, nitride) layer and may be deposited by sputtering, evaporation, sol-gel, or polymerization method.

Laminate materials in accordance with the instant invention include any material capable of providing mechanical support to the multilayer photovoltaic device upon removal of the substrate. Representative materials for the laminate include plastics and fiberglass.

Removal of the substrate may be accomplished by delamination; dissolution; laser ablation; or mechanical abrasion. Delamination refers generally to a process of peeling the substrate away from the stack of layers formed thereon. Delamination may include a step of heating or cooling to exploit differences in thermal expansion or contraction between the substrate and the stack of layers formed thereon. Differences in the extent of thermal expansion or contraction may facilitate peeling or separation of the substrate from the stack of layers formed thereon. Dissolution of the substrate may occur through chemical means. Metal substrates, for example, may be dissolved with an acid treatment. In one embodiment, dissolution occurs through an electrochemical process. Laser ablation is a process in which a high power laser is directed to the substrate to remove it. The laser delivers energy to the substrate, causing it to heat up and to vaporize or otherwise be ejected. In one embodiment, laser ablation loosens the substrate and facilitates delamination.

In another embodiment, the substrate is removed by incorporating a sacrificial layer in the stack of layers formed on the substrate. In this embodiment, a sacrificial layer is deposited between the substrate and the photovoltaic stack and is selected to be readily removable so as to permit separation of the substrate from the photovoltaic stack. The sacrificial layer may be selected on the basis of a solubility contrast with the layers of the photovoltaic stack. The sacrificial layer may be selectively dissolved in a particular solvent that does not cause dissolution of the layers of the photovoltaic stack. In the art of lithography, for example, a variety of masking and etching chemistries have been devised that feature differential solubility of a masking material and an underlying material that is being patterned. In these chemistries, once lithographic patterning is completed, a developer solution dissolves and washes away residual masking material. In one embodiment, the sacrificial layer is an organic material, such as a polymer, and the photovoltaic stack comprises inorganic materials. It is well known in the chemical arts that inorganic materials are impervious to many solvents effective at dissolving organic materials.

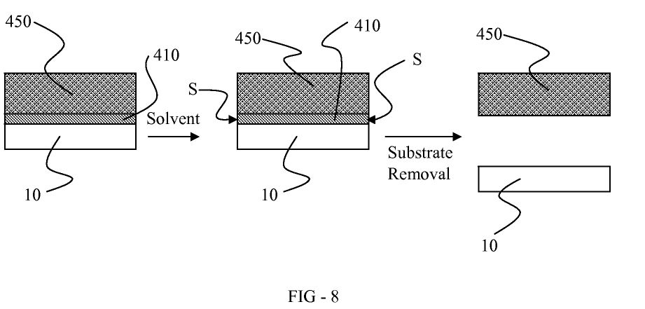

A schematic depiction of substrate removal via use of a sacrificial layer is presented in FIG. 8, which shows substrate 10 with sacrificial layer 410 and photovoltaic stack 450. Photovoltaic stack 450 is a block representation of a single or multilayer photovoltaic device in accordance with the instant invention and is presented as a single element in FIG. 8 for convenience. It is to be understood that the sacrificial layer concept described herein is generally applicable to any combination of one or more layers of the type described herein, including, without limitation, the specific illustrative embodiments described hereinabove.

In FIG. 8, sacrificial layer 410 is removed by the action of solvent S, which penetrates sacrificial layer 410 at its edges to soften or dissolve it so that substrate 10 can be separated from photovoltaic stack 450. Solvent S may be an aqueous or organic solvent. The notion of a sacrificial layer may be extended beyond separation by chemical means to separation by physical means. The sacrificial layer may, for example, be more brittle than the photovoltaic stack so that application of a fracture force suffices to separate the photovoltaic stack from the substrate. Similarly, the sacrificial layer may have a yield stress below the yield stress of the photovoltaic stack so that the application of a shear force causes a deformation of the sacrificial layer to permit a separation of the substrate from the photovoltaic stack. Alternatively, the sacrificial layer may be selected to soften or melt at temperatures that produce no harmful effects on the photovoltaic stack. If the sacrificial layer, for example, melts, the substrate may readily be peeled or slid from the photovoltaic stack.

The principles of the instant invention extend to both batch and continuous web manufacturing. In batch processing, deposition of one or more layers of a photovoltaic device occurs sequentially on individual wafers or substrates. Each wafer or substrate is handled separately and generally has a maximum lateral dimension on the order of several inches to a few feet. In batch processing, the wafer or substrate is commonly held stationary during deposition of a particular layer.

In continuous web deposition, the substrate is a mobile, extended web that is continuously conveyed through a series of deposition or processing units. The web typically has a dimension of a few inches to a few feet in the direction transverse to the direction of transport of the web through the manufacturing apparatus and a dimension of a few hundred to a few thousand feet in the direction of web transport. In continuous manufacturing, the web is generally in motion during deposition and processing of the individual layers of a multilayer device. The web of substrate material may be continuously advanced through a succession of one or more operatively interconnected, environmentally protected deposition chambers, where each chamber is dedicated to the deposition of a particular layer or layers of a photovoltaic device structure onto either the web or a layer previously deposited on the web. The series of chambers may also include chambers dedicated to processes such as patterning, heating, annealing, cleaning, or substrate removal. By making multiple passes through the succession of deposition chambers, multiple layers of various configurations (including patterned or unpatterned layers as described hereinabove) may be obtained.

Those skilled in the art will appreciate that the methods and designs described above have additional applications and that the relevant applications are not limited to the illustrative examples described herein. The present invention may be embodied in other specific forms without departing from the essential characteristics or principles as described herein. The embodiments described above are to be considered in all respects as illustrative only and not restrictive in any manner upon the scope and practice of the invention. It is the following claims, including all equivalents, which define the true scope of the instant invention.

We claim:

1. A method of forming a photovoltaic device comprising:
providing a substrate;
forming one or more layers over said substrate, said one or more layers including a first layer;
forming a photovoltaic material on said one or more layers; and
removing said substrate, said removing exposing a first surface of said first layer;
wherein light incident to said first surface is transmitted through said one or more layers to said photovoltaic material.

2. The method of claim 1, wherein said substrate is opaque.

3. The method of claim 2, wherein said opaque substrate comprises a metal.

4. The method of claim 2, wherein said opaque substrate comprises steel.

5. The method of claim 1, wherein said substrate comprises a plastic or polymer.

6. The method of claim 5, wherein said substrate comprises a polyimide.

7. The method of claim of claim 1, wherein said photovoltaic material comprises silicon.

8. The method of claim 7, wherein said silicon is in the form of amorphous silicon, nanocrystalline silicon, or microcrystalline silicon.

9. The method of claim 7, wherein said photovoltaic material further comprises hydrogen or fluorine.

10. The method of claim 7, wherein said photovoltaic material further comprises germanium.

11. The method of claim 1, wherein said photovoltaic material comprises Te, Se, or S.

12. The method of claim 11, wherein said photovoltaic material further comprises Cd, Zn, In or Ga.

13. The method of claim 1, wherein said photovoltaic material comprises an organic compound.

14. The method of claim 1, wherein said photovoltaic material includes a first region and a second region.

15. The method of claim 14, wherein said first region is an n-type region or a p-type region.

16. The method of claim 15, wherein said second layer is an n-type region or a p-type region.

17. The method of claim 16, wherein said photovoltaic material further includes a third region interposed between said first region and said second region.

18. The method of claim 14, wherein said first region comprises silicon.

19. The method of claim 18, wherein said first region further comprises germanium.

20. The method of claim 18, wherein said first region further comprises hydrogen or fluorine.

21. The method of claim 18, wherein said second region comprises silicon or germanium.

22. The method of claim 1, wherein said substrate is removed by delamination.

23. The method of claim 1, wherein said substrate is removed by a chemical treatment.

24. The method of claim 23, wherein said chemical treatment comprises dissolution of said substrate.

25. The method of claim 1, wherein said first layer is a sacrificial layer.

26. The method of claim 25, wherein said sacrificial layer comprises an organic material.

27. The method of claim 26, wherein said organic material is a polymer.

28. The method of claim 25, wherein said sacrificial layer is soluble in an aqueous or organic solvent.

29. The method of claim 25, wherein the yield strength of said sacrificial layer is less than the yield strength of said photovoltaic material.

29. The method of claim 25, wherein said substrate is removed by dissolving, softening, melting, peeling, or fracturing said sacrificial layer.

30. The method of claim 1, further comprising patterning said photovoltaic material.

31. The method of claim 30, wherein said patterning includes laser scribing.

32. The method of claim 30, wherein said patterning includes masking.

33. The method of claim 32, wherein said patterning further includes etching.

34. The method of claim 30, wherein said patterning segments said photovoltaic material into a plurality of electrically isolated regions.

35. The method of claim 30, further comprising forming a conductive material over said patterned photovoltaic material.

36. The method of claim 1, wherein said first layer comprises a first conductive material.

37. The method of claim 36, further comprising patterning said first conductive material.

38. The method of claim 36, wherein said first conductive material is transparent.

39. The method of claim 38, wherein said transparent conductive material is an oxide.

40. The method of claim 39, wherein said oxide comprises zinc, indium or tin.

41. The method of claim 39, further comprising forming a transparent protective layer between said transparent conductive material and said substrate.

42. The method of claim 38, further comprising forming a second conductive material over said photovoltaic material.

43. The method of claim 42, wherein said second conductive material is reflective.

44. The method of claim 42, wherein said second conductive material comprises a metal.

45. The method of claim 44, wherein said metal is aluminum, silver, or copper.

46. The method of claim 42, wherein said second conductive material is an oxide, sulfide, selenide, or telluride.

47. The method of claim 42, wherein said second conductive material includes a first region and a second region.

48. The method of claim 47, wherein said first region is transparent and said second region is reflective.

49. The method of claim 42, further comprising patterning said first conductive material, patterning said photovoltaic material, and patterning said second conductive material.

50. The method of claim 49, wherein said patterning of said first conductive material, said photovoltaic material and said second conductive material forms a plurality of photovoltaic devices; each of said photovoltaic devices including a first contact comprising said first conductive material, a segmented region of said photovoltaic material, and a second contact comprising said second conductive material, wherein said first and second contacts are in electrical communication with said segmented region of said photovoltaic material.

51. The method of claim 50, wherein said plurality of photovoltaic devices are connected in series.

52. The method of claim 49, wherein the patterned features of said first conductive layer are staggered relative to the patterned features of said photovoltaic material.

53. The method of claim 52, wherein the patterned features of said second conductive layer are staggered relative to the patterned features of said photovoltaic material.

54. The method of claim 1, further comprising forming a laminate over said photovoltaic material.

55. The method of claim 54, wherein said laminate is a plastic or fiberglass.

56. The method of claim 54, further comprising forming an adhesive layer between said laminate and said photovoltaic material.
